(19) United States
(12) Patent Application Publication
(10) Pub. No.: US 2012/0181080 A1
(43) Pub. Date: Jul. 19, 2012

(54) COMBINATION GLASS/CERAMIC PARTICLES FOR EMI SHIELDING

(76) Inventor: William G. Lionetta, Winchester, MA (US)

(21) Appl. No.: 12/144,707

(22) Filed: Jun. 24, 2008

Related U.S. Application Data
(60) Provisional application No. 60/948,755, filed on Jul. 10, 2007.

(51) Int. Cl. H05K 9/00; H01B 1/08; H01B 1/20; H01B 1/06

(52) U.S. Cl. 174/388; 252/500

(57) ABSTRACT

Electromagnetic interference (“EMI”) absorbing particulate filler for EMI shielding formed of particles of one of a ceramic or glass material which are encapsulated by the other one of the materials, and EMI shielding materials and assemblies formed thereof.

### CROSS-REFERENCE TO RELATED APPLICATIONS

This application claims priority to U.S. provisional application Ser. No. 60/948,755, filed Jul. 10, 2007, the disclosure of which is expressly incorporated herein by reference.

### BACKGROUND OF THE INVENTION

The present invention relates broadly to electromagnetic interference (EMI) materials and shields, such as cases, housings, or parts thereof such as covers, or board-level shields such as single or multi-compartment covers or “cans,” for mobile, i.e., cellular telephone handsets, telecommunication base stations, and other electronic devices, and particularly to materials and shields formed of a composite plastic or other polymeric material which is filled with a magnetic filler to render the material EMI absorptive.

The operation of electronic devices such as televisions, radios, computers, medical instruments, business machines, communications equipment, and the like is attended by the generation of electromagnetic radiation within the electronic circuitry of the equipment. As is detailed in U.S. Pat. Nos. 5,202,536; 5,142,101; 5,105,056; 5,028,739; 4,952,448; and 4,857,668, such radiation often develops as a field or as transients within the radio frequency band of the electromagnetic spectrum, i.e., between about 10 KHz and 10 GHz, and is termed “electromagnetic interference” or “EMI” as being known to interfere with the operation of other proximate electronic devices.

To attenuate EMI effects, shielding having the capability of absorbing and/or reflecting EMI energy may be employed both to confine the EMI energy within a source device, and to insulate that device or other “target” devices from other source devices. Such shielding is provided as a barrier which is interposed between the source and the other devices, and typically is configured as an electrically conductive and grounded housing which encloses the device, or as a “can” which covers a discrete component or componentry of the device. The housing or can may be formed of a metal such as steel, aluminum, or magnesium, or alternatively, of a plastic or other polymeric material which is filled to be electrically-conductive, such as is described in U.S. Pat. Nos. 5,397,608; 5,366,664; 5,213,889; 5,137,766; 5,019,450; 4,973,514; 4,816,184; 4,664,971; and 4,559,262, and in WO 02/43456 and 02/02686, or which may be provided with a conductive coating generally applied across the interior surfaces of the housing. A conductive gasket may be used to provide electrical continuity between the various mating parts.

Such housings, cans, and methods are further described in commonly-assigned U.S. Pat. Nos. 6,348,654 and 5,566,055, US20030015334, WO02/093997 and WO02/093996, and in U.S. Pat. Nos. 6,431,884; 6,256,878; 6,090,728; 5,847,317; 5,811,050; 5,571,991; 5,475,919; 5,473,111; 5,442,153; 5,397,857; 5,180,639; 5,170,009; 5,150,282; 5,047,260; and 4,714,623; WO02/43456; WO01/97583; WO00/29635; WO99/43191; WO99/40769; WO98/54942; WO98/47340; WO97/26782; EP1148774; EP0936045; EP0940068; and DE19728839, and in the following publications of the Chomerics Division of Parker Hannifin Corporation (Woburn, Mass.): “CHO-SHIELD® Conductive Compounds;” “CHO-SHIELD® EMI Shielding Covers,” Technical Bulletin 22, (1996); “CHO-VER SHIELD® EMI Shielding Plastic Cover with Molded Conductive Elastomeric Gasket,” (1999); “CHO-SHIELD® 2052 Conductive Coating,” Technical Bulletin 48, (2000); “CHO-SHIELD® 2054 Conductive Coating,” Preliminary Product Data Sheet, (2000); and “CHO-SHIELD® 2056 High Performance Conductive Coating,” Preliminary Product Data Sheet.

In view of the foregoing, it may be appreciated that many different types of materials and constructions have been employed in the production of EMI shields. As electronic devices continue to proliferate, it is believed that additional EMI shielding alternatives and options would be well-received by the electronics industry.

### SUMMARY OF THE INVENTION

The present invention relates broadly to electromagnetic interference (EMI) materials and shields formed of a composite plastic or other polymeric material. More particularly the invention relates to a magnetic, dielectric, lossy or otherwise EMI-absorptive filler for such materials and shields.

Such filler may glass particles which are coated or otherwise encapsulated within a layer of a ceramic which may be magnetic, lossy, or otherwise EMI-absorptive. The glass particles may be hollow or solid.

Alternatively, such filler may be ceramic particles which are coated or otherwise encapsulated within a layer of a glass. The ceramic particles may be magnetic, lossy, or otherwise EMI-absorptive, and may be solid or hollow.

### BRIEF DESCRIPTION OF THE DRAWINGS

For a fuller understanding of the nature and objects of the invention, reference should be had to the following detailed description taken in connection with the accompanying drawings wherein:

FIG. 1 is a cutaway perspective view of a representative hollow glass/ceramic filler particle in accordance with the present invention; and

FIG. 2 is a cutaway perspective view of a representative solid glass/ceramic filler particle in accordance with the present invention.

The drawings will be described further in connection with the following Detailed Description of the Invention.

### DETAILED DESCRIPTION OF THE INVENTION

Certain terminology may be employed in the following description for convenience rather than for any limiting purpose. For example, the terms “forward” and “rearward,” “front” and “rear,” “right” and “left,” “upper” and “lower,” “top” and “bottom,” and “right” and “left” designate directions in the drawings to which reference is made, with the terms “inward,” “inner,” “interior,” or “inboard” and “outward,” “outer,” “exterior,” or “outboard” referring, respectively, to directions toward and away from the center of the referenced element, the terms “radial” or “vertical” and “axial” or “horizontal” referring, respectively, to directions or planes perpendicular and parallel to the longitudinal central axis of the referenced element. Terminology of similar import other than the words specifically mentioned above likewise is to be considered as being used for purposes of convenience rather than in any limiting sense. Further, the term “EMI shielding” should be understood to include, and to be used interchangeably with, electromagnetic compatibility (EMC), electrical conduction and/or grounding, corona shielding, radio frequency interference (RFI) shielding, and anti-static, i.e., electro-static discharge (ESD) protection, and the terms “magnetic,” “dielectric,” “ferritic,” or “lossy” to be used interchangeably with EMI absorbing, absorptive, dissipating, dissipative, or attenuating, or as otherwise having a capability to attenuate electromagnetic energy by absorption or another dissipation mechanism.

In the figures, elements having an alphanumeric designation may be referenced herein collectively or in the alternative, as will be apparent from context, by the numeric portion of the designation only. Further, the constituent parts of various elements in the figures may be designated with separate reference numerals which shall be understood to refer to that constituent part of the element and not the element as a whole. General references, along with references to spaces, surfaces, dimensions, and extents, may be designated with arrows or underscores.

For the illustrative purposes of the discourse to follow, the EMI-absorbing particulate filler of the invention herein involved is principally described in connection with its use in a plastic or other polymeric composite material such as for use in the extrusion, molding or other production of an EMI shield which may be, for example, a board-level cover or “can” which is mountable onto or over a printed circuit board (PCB) for enclosing the PCB or a component or circuit thereof, or which may be, for example, a housing, case, or other enclosure of an electronic device such as a mobile, i.e., cellular, telephone handset, or other electronic device such as a personal communications services (PCS) handset, PCMCIA card, global positioning system (GPS), radio receiver, personal digital assistant (PDA), notebook or desktop personal computer (PC), cordless telephone handset, network router or server, medical electronics device, modem, wireless communication base station, telemetry device, telematic component or system, or the like. It will be appreciated, however, that aspects of the present invention may find use in other EMI shielding applications, and in other forms such as gaskets, gap fillers, adhesives, and caulk. Such uses and applications therefore should be considered to be expressly within the scope of the present invention.

In accordance with the precepts of the present invention, an EMI-absorptive particulate material is provided such as for use as a filler in a composite material have a continuous phase of a plastic or other polymeric material and a discrete phase of the particulate material dispersed in the continuous phase. Such composite material, which may be thermoplastic or thermosetting, may be molded, extruded, stamped, or otherwise processed to form a wall or other portion of EMI-shielding housing, cover, can, or other shield. Such shield, in turn, may be disposed over or as enclosing or otherwise adjacent the circuitry of an electronic device. Such composite materials, shields, and assemblies are further described in commonly-assigned U.S. Pat. No. 7,326,862.

The composite material may be formulated as a blend or other admixture of a resin, plastic, elastomeric, or other or other polymeric component and the EMI-absorptive particulate filler of the present invention. The polymeric component, which itself may be a blend or other admixture, may be a thermoplastic or thermoset, and specifically may be selected as depending upon one or more of operating temperature, hardness, chemical compatibility, resiliency, compliancy, compression-deflection, compression set, flexibility, ability to recover after deformation, modulus, tensile strength, elongation, force defection, flammability, or other chemical or physical property. Depending upon the application, suitable materials may include, particularly, polyurethanes, silicones, fluorosilicones, polycarbonates, ethylene vinyl acetates (EVA), acrylonitrile-butadiene-styrenes (ABS), polysulfones, acrylics, polyvinyl chlorides (PVC), polyphenylene ethers, polystyrenes, polyamides, nylons, polyolefins, poly(ether ether ketones), polyimides, polyetherimides, polybutylene terephthalates, polyethylene terephthalates, fluoropolymers, polyesters, acetals, liquid crystal polymers, polymethylacrylates, polyphenylene oxides, polystyrenes, epoxies, phenolics, chlorosulfonates, polybutadienes, buna-N, butyls, neoprenes, nitriles, polyisoprenes, natural rubbers, and copolymer rubbers such as styrene-isoprene-styrenes (SIS), styrene-butadiene-styrenes (SBS), ethylene-propylenes (EPR), ethylene-propylene-diene monomers (EPDM), nitrile-butadienes (NBR), and styrene-butadienes (SBR), and copolymers and blends thereof. Any of the forgoing materials may be used unfoamed or, if required by the application, blown or otherwise chemically or physically processed into an open or closed cell foam.

The polymeric component generally may form a binder or other continuous or matrix phase into which the particulate filler may be dispersed as a discrete phase. The filler generally may be included within the binder in a proportion sufficient to provide the level of EMI shielding effectiveness which is desired for the intended application. For most applications, an EMI shielding effectiveness of at least 10 dB, and usually at least 20 dB, and preferably at least about 60 dB or higher, over a frequency range of from about 10 MHz to 10 GHz is considered acceptable. Such effectiveness translates to a filler proportion which generally is between about 10-80% by volume or 50-90% by weight, based on the total volume or weight, as the case may be, of the compound, and a bulk or volume resistivity of not greater than about 1,000 Ω-cm, and/or a surface resistance of not greater than about 1000 Ω/sq., although it is known that comparable EMI shielding effectiveness may be achieved at lower conductivity levels through the use of an EMI absorptive filler. As is also known, the ultimate shielding effectiveness of the composite, such as formed into a housing, cover, or can, will vary based on the amount of the EMI-absorptive filler, and of other fillers, such as electrically-conductive fillers electrically-conductive, and on the thickness of the composite.

Suitable electrically-conductive fillers which may be employed in combination with the EMI-absorptive of the invention include: nonmetals such as carbon, graphite, and inherently, i.e., intrinsically, conductive polymers; noble and non-noble metals such as gold, silver, nickel, copper, tin, aluminum, and nickel; noble or non-noble metal-plated, clad, metallized, or otherwise coated noble and non-noble metals such as gold or silver-plated copper, nickel, or aluminum, and tin or nickel-plated copper, silver, bismuth, indium, and lead; noble or non-noble metal coated non-metals such as gold, silver and/or nickel-plated or clad graphite, i.e., gold plated nickel clad graphite, glass, ceramics, plastics, elastomers, and mica; non-metal coated metal and non-metals; and combinations and mixtures thereof. The electrically-conductive filler specifically may be selected as depending upon one or more of conductivity, resin demand, hardness, chemical compatibility, such as with the polymeric component, and cost.

Additional fillers and additives may be included in the formulation of the composite depending upon the requirements of the particular application envisioned. Such fillers and additives, which may be functional or inert, may include wetting agents or surfactants, pigments, dispersants, dyes, and other colorants, opacifying agents, foaming or anti-foaming agents, anti-static agents, coupling agents such as titanates, chain extending oils, tackifiers, flow modifiers, pigments, lubricants such as molybdenum disulfide (MoS₂), silanes, peroxides, film-reinforcing polymers and other agents, stabilizers, emulsifiers, antioxidants, thickeners, and/or flame retardants and other fillers such as aluminum trihydrate, antimony trioxide, metal oxides and salts, intercalated graphite particles, phosphate esters, decabromodiphenyl oxide, borates, phosphates, halogenated compounds, glass, silica, which may be fumed or crystalline, silicates, mica, ceramics, and glass or polymeric microspheres. Typically, these fillers and additives are blended or otherwise admixed with the formulation, and may comprise between about 0.05-80% or more by total volume thereof. The formulation of the composite material may be compounded in a conventional mixing apparatus as an admixture of the polymer and filler components, and any additional fillers or additives.

In general, the EMI-absorptive filler of the invention may be of any shape, or combination of shapes, and is referred broadly herein as being “particulate,” which should be understood to include solid or hollow spheres and microspheres or microballoons, flakes, platelets, fibers, rods, irregularly-shaped particles, fibers, which may be chopped or milled or whiskers, and powders. For many applications the filler take the form of solid or hollow spheres or microspheres to better assure uniform dispersal and homogeneous mechanical and shielding properties. The particle size or distribution of the filler, which may be a diameter, imputed diameter, length, or other dimension of the particulate typically will range from about 0.01 mil (0.25 μm) to about 100 mils (2500 μm), and from about 0.004 inch (0.1 mm) to about 1 inch (25 mm) for fibers.

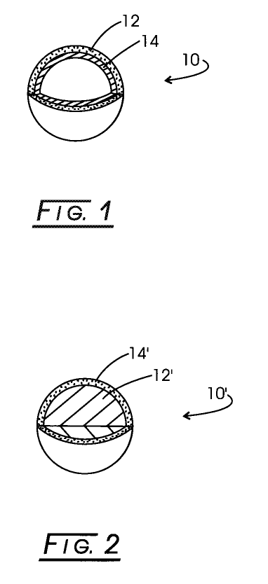

Referring now to the figures wherein corresponding reference characters are used to designate corresponding elements throughout the several views with equivalent elements being referenced with prime or sequential alphanumeric designations, an illustrative hollow spherical or microspherical particle in accordance with the present invention is depicted generally at 10 in FIG. 1. Such particle 10 is formed of an inner hollow sphere, 12, formed of one of a ceramic or a glass material, and an outer layer, 14, of the other one of the ceramic or glass material at least partly encapsulating the inner hollow sphere 12. That is, the inner hollow sphere 12 may be a hollow glass sphere or microsphere, with the outer layer 14 being a ceramic coating or other layer on the sphere 12. Alternatively, the inner hollow sphere 12 may be a ceramic sphere or microsphere, with the outer layer 14 being a glass coating or other layer.

Likewise, as is shown in FIG. 2, particle 10, now referenced generally at 10′, may be formed of an inner solid sphere, 12′, and an outer layer, 14′. As before, the inner solid sphere 12′ may be formed of one of a ceramic or a glass material, with the outer layer 14 being formed of the other one of the ceramic or glass material. Depending on the size of the spheres 12 or 12′, which may range from about 0.01 mil (0.25 μm) to about 100 mils (2500 μm), the coating thickness of the layer 14 or 14′ may range from about 0.01 mil (0.25 μm) to about 100 mils (2500 μm). In any of the embodiments, the outer layer 14 or 14′ may be single layer or a multi-layer formed of different glass or ceramic materials.

Suitable ceramic materials include oxides, non-oxides such as carbides, borides, nitrides, silicides, and ferrites (i.e., ceramic semi-conductive materials comprising a mixture of several metallic oxides such as manganese, magnesium, and nickel zinc ferrite, and/or bivalent or trivalent substitutions of copper, cobalt, aluminum, lithium, and the like). Representative oxide and non-oxide ceramic materials include aluminum oxide (alumina), zirconium oxide (zirconia), zirconium dioxide, zinc oxide, beryllium oxide, antimony oxide, magnesium oxide, silicon carbide, titanium diboride, aluminum nitride, and boron nitride. Suitable glass materials include silica, borosilica, and non-silica glass, and blends or other mixtures of these materials.

The coating or other layer of the glass or ceramic material may be applied to the underlying particle using conventional processes such as vapor deposition, ion plasma deposition, plasma spray, thermal deposition, and fluidized bed coating.

As it is anticipated that certain changes may be made in the present invention without departing from the precepts herein involved, it is intended that all matter contained in the foregoing description shall be interpreted as illustrative and not in a limiting sense. All references including any priority documents cited herein are expressly incorporated by reference.

What is claimed is:

1. An electromagnetic interference (“EMI”) absorbing particulate filler comprising:
particles formed of a material selected from the group consisting of: (I) ceramics; and (II) glasses, whereby
the particles comprising the material (I) or (II) are at least partly encapsulated by the other of the materials (I) or (II).

2. The particulate filler of claim 1 wherein the particles are generally spherical.

3. The particulate filler of claim 2 wherein the particles are solid or hollow.

4. The particulate filler of claim 1 wherein the filler has a mean average particle size of between about 0.01-10 mil (0.25-250 μm).

5. The particulate filler of claim 1 wherein the ceramics (I) are selected from the group consisting of oxides, non-oxides, and mixtures thereof, and the glasses (II) are selected from the group consisting of silica glass, borosilica glass, non-silica glass, and mixtures thereof.

6. The particulate filler of claim 1 wherein the ceramics (I) are magnetic, dielectric, ferritic, or lossy.

7. A composite material comprising an admixture of:
(a) a polymeric component; and
(b) an electromagnetic interference (“EMI”) absorbing particulate filler component comprising particles formed of a material selected from the group consisting of: (I) ceramics; and (II) glasses, whereby the particles comprising the material (I) or (II) are at least partly encapsulated by the other of the materials (I) or (II).

8. The material of claim 7 which comprises, by total weight of the components (a) and (b), between about 20-80% of the filler component.

9. The material of claim 7 wherein the filler component has a mean average particle size of between about 0.01-10 mil (0.25-250 μm).

10. The material of claim 7 which exhibits an EMI shielding effectiveness of at least about 60 dB substantially over a frequency range of between about 10 MHz and about 10 GHz.

11. The material of claim 7 wherein the polymeric component is selected from the group consisting of epoxies, phenolics, poly(ether ether ketones), polyimides, polyolefins, polyetherimides, polybutylene terephthalates, polyethylene terephthalates, nylons, polyamides, fluoropolymers, polysulfones, polyesters, acetal homo and copolymers, liquid crystal polymers, polyacrylics, polymethylacrylates, poly(ester and ether urethanes), polyurethanes, acrylonitrile-butadiene-styrene, polyvinyl chlorides, polyphenylene ethers, polyphenylene oxides, polystyrenes, polycarbonates, and copolymers and blends thereof.

12. The material of claim 7 wherein the polymeric component comprises one or more thermosetting or thermoplastic polymers or co-polymers, or a blend thereof.

13. The material of claim 7 wherein the ceramics (I) are selected from the group consisting of oxides, non-oxides, and mixtures thereof, and the glasses (II) are selected from the group consisting of silica glass, borosilica glass, non-silica glass, and mixtures thereof.

14. The material of claim 7 wherein the ceramics (I) are magnetic, dielectric, ferritic, or lossy.

15. The material of claim 7 having a volume resistivity of not greater than about 1,000 Ω-cm.

16. An assembly for the EMI shielding of circuitry of an electronic device, the assembly comprising an EMI shield disposed adjacent the circuitry, the shield being formed of a composite material comprising an admixture of:
(a) a polymeric component; and
(b) an electromagnetic interference (“EMI”) absorbing particulate filler component comprising particles formed of a material selected from the group consisting of: (I) ceramics; and (II) glasses, whereby
the particles comprising the material (I) or (II) are at least partly encapsulated by the other of the materials (I) or (II).

17. The assembly of claim 16 wherein the composite material comprises, by total weight of the components (a) and (b), between about 20-80% of the filler component.

18. The assembly of claim 16 wherein the filler component has a mean average particle size of between about 0.01-10 mil (0.25-250 μm).

19. The assembly of claim 16 wherein the shield exhibits an EMI shielding effectiveness of at least about 60 dB substantially over a frequency range of between about 10 MHz and about 10 GHz.

20. The assembly of claim 16 wherein the polymeric component is selected from the group consisting of epoxies, phenolics, poly(ether ether ketones), polyimides, polyolefins, polyetherimides, polybutylene terephthalates, polyethylene terephthalates, nylons, polyamides, fluoropolymers, polysulfones, polyesters, acetal homo and copolymers, liquid crystal polymers, polyacrylics, polymethylacrylates, poly(ester and ether urethanes), polyurethanes, acrylonitrile-butadiene-styrene, polyvinyl chlorides, polyphenylene ethers, polyphenylene oxides, polystyrenes, polycarbonates, and copolymers and blends thereof.

21. The assembly of claim 16 wherein the polymeric component comprises one or more thermosetting or thermoplastic polymers or co-polymers, or a blend thereof.

22. The assembly of claim 16 wherein the ceramics (I) are selected from the group consisting of oxides, non-oxides, and mixtures thereof, and the glasses (II) are selected from the group consisting of silica glass, borosilica glass, non-silica glass, and mixtures thereof.

23. The assembly of claim 16 wherein the ceramics (I) are magnetic, dielectric, ferritic, or lossy.

24. The assembly of claim 16 wherein the composite material has a volume resistivity of not greater than about 1,000 Ω-cm.
